(19) United States
(12) Patent Application Publication
(10) Pub. No.: US 2014/0145715 A1
(43) Pub. Date: May 29, 2014

(54) DEVICE AND METHOD FOR CHARACTERIZING A LASER BEAM

(71) Applicants: Geert Rikken, Escalquens (FR); Remy Battesti, Labarthe Sur leze (FR); Andrei Ben-Amar Baranga, Omer (IL); Mathilde Fouche, Toulouse (FR); Carlo Ritto, Ramonville St Agne (FR)

(72) Inventors: Geert Rikken, Escalquens (FR); Remy Battesti, Labarthe Sur leze (FR); Andrei Ben-Amar Baranga, Omer (IL); Mathilde Fouche, Toulouse (FR); Carlo Ritto, Ramonville St Agne (FR)

(73) Assignee: CENTRE NATIONAL DE LA RECHERCHE SCIENTIFIQUE, PARIS (FR)

(21) Appl. No.: 13/820,515

(22) PCT Filed: Sep. 2, 2011
(86) PCT No.: PCT/EP2011/065227

§ 371 Date: Jun. 27, 2013

(30) Foreign Application Priority Data
Sep. 3, 2010 (FR) 1057007

(51) Int. Cl. G01R 33/12

(52) U.S. Cl. CPC G01R 33/1215
USPC 324/244

(57) ABSTRACT

A device and a method making it possible to measure a magnetization generated within an active medium, or to characterize a linearly polarized electromagnetic wave when said active medium exhibits an Inverse Cotton-Mouton effect, comprises in combination at least the following elements: an active medium in which a linearly polarized electromagnetic wave propagates, a means for producing a transverse magnetic field with respect to the direction of propagation of said electromagnetic wave, a device for measuring the electrical signal suitable for manifesting the magnetization generated within said active medium by said electromagnetic wave.

The invention relates to a device and a method making it possible notably to characterize a pulsed laser beam of high energy or else a continuous laser beam. Thus, the present invention is used to measure the instantaneous power of a laser beam, or the total energy of a laser pulse and/or the polarization of the beam.

It also applies when it is desired to measure the magnetization generated within an active medium exhibiting an Inverse Cotton-Mouton effect.

In general, the power of high-power lasers is measured by total or partial absorption of the laser beam. This leads to consumption of the energy of the laser at the level of the target used to execute the measurement. This is manifested by a loss of energy of the beam and presents the drawback of not being able to use the laser beam, simultaneously with the measurement of its energy or of its power.

To ascertain the temporal shape, it is known to extract a part of the beam and to send it to another apparatus based on fast photodiodes. To determine the polarization of the laser beam it is necessary to possess polarizers specially designed for high powers and to perform the measurement of the energy of the pulse as a function of the polarization.

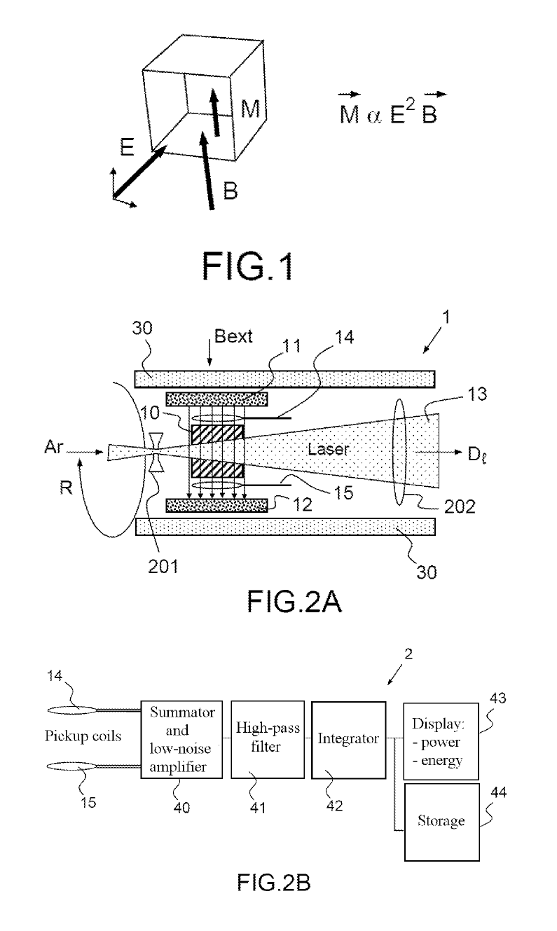

FIG. 1 presents the inverse Cotton-Mouton effect or ICME produced in a medium 1 by a laser beam propagating in the medium in the presence of a magnetic field transverse to the direction of a light beam.

The publication by Zon. B. A entitled “observation of inverse Cotton-Mouton effect in the magnetically ordered crystal (Lu, Bi)₃(FE, Ga)₅O₁₂, published at the JEPT Let. 45 (1987) 5, pages 272-275 describes the inverse Cotton-Mouton effect. This publication describes the measurement of the magnetization induced by a pulsed laser beam in a magnetic film which is situated in a static exterior magnetic field oriented parallel to the direction of propagation of the pulsed laser beam.

The publication by Marmo S. I entitled “Electric field induced magnetization and inverse Cotton-Mouton effect in atomic gases”, published in Physics letters A, 202 (1995), pages 201-205 discloses the prediction of the inverse Cotton-Mouton effect in atomic and molecular systems.

### DEFINITIONS OF THE TERMS USED

In the subsequent description the expression “active medium” designates a material, a crystal, a glass, a gas, a liquid which, when it is subjected to a magnetic field, will exhibit an inverse Cotton-Mouton effect.

The term “characterize or characterization” of a laser beam will be used to refer to a measurement of instantaneous power of the beam, a measurement of power or else the determination of the polarization of the beam.

The invention relates to a device making it possible to measure a magnetization generated within an active medium or to characterize a linearly polarized electromagnetic wave when said active medium exhibits an Inverse Cotton-Mouton effect, characterized in that it comprises in combination at least the following elements:
an active medium in which a linearly polarized electromagnetic wave propagates,
a means for producing a transverse magnetic field Bₜ, with respect to the direction of propagation of said electromagnetic wave,
a device for measuring the electrical signal manifesting the magnetization generated within said active medium through which said electromagnetic wave passes.

In the case of an electromagnetic wave, passing through an active medium, the measurement device makes it possible to characterize the electromagnetic wave by at least one of the following parameters: the instantaneous power of the electromagnetic wave, the integral power or else the polarization of the wave.

According to one embodiment, the electromagnetic wave is a pulsed laser beam and the measurement device characterizes the pulsed laser beam by at least one of the following parameters: the instantaneous power of a pulse of said laser beam, the integral power of a pulse of said laser beam, the polarization of said laser beam.

According to another embodiment, the electromagnetic wave is a continuous laser beam and the measurement device characterizes the laser beam by at least one of the following parameters: the instantaneous power of said laser beam, the integral power of said laser beam, the polarization of said laser beam, the magnetic field being variable over time.

Said active medium is, for example, subjected to a static exterior magnetic field Bₑₓₜ which is variable or constant over time.

The device for measuring the signal comprises, for example, at least one coil of pickup type.

The device for measuring the signal can comprise at least two coils of pickup type placed on either side of the active medium, the normal to their surface, being oriented substantially parallel to the magnetic field Bₑₓₜ.

The electronic device for measuring the signal manifesting the instantaneous energy value of the electromagnetic wave, or the value of the power of said electromagnetic wave comprises the following elements:
a summator and low-noise amplifier whose function is to eliminate the spurious noise not corresponding to the signal associated with the inverse Cotton-Mouton effect, the summed and amplified signal being transmitted to
a high-pass filter, and then to an integrator before being transmitted to a display device and/or to a storage memory.

The device comprises, for example, a rotating mount in which are disposed the active medium, the means for producing the magnetic field.

The device can comprise an optical adaptation system.

Said active medium is a crystal of TGG or Terbium Gallium Garnet.

The invention also relates to a method for measuring a magnetization generated within an active medium, when said active medium exhibits an Inverse Cotton-Mouton effect, the method being implemented within a device exhibiting one of the aforementioned characteristics, the method comprising at least the following steps:
transmitting in an active medium a linearly polarized electromagnetic wave,
generating a transverse magnetic field Bₜ with respect to the direction of propagation Dₗ of said electromagnetic wave,
measuring the electrical signal manifesting the magnetization generated within said active medium by said electromagnetic wave.

Other characteristics and advantages of the present invention will be more apparent on reading the description of one or more embodiments given by way of wholly nonlimiting illustration, together with the figures which represent:

FIG. 1, a representation of the inverse Cotton-Mouton effect,

FIG. 2A, an exemplary measurement device according to the invention, and FIG. 2B, an exemplary associated electronic circuit,

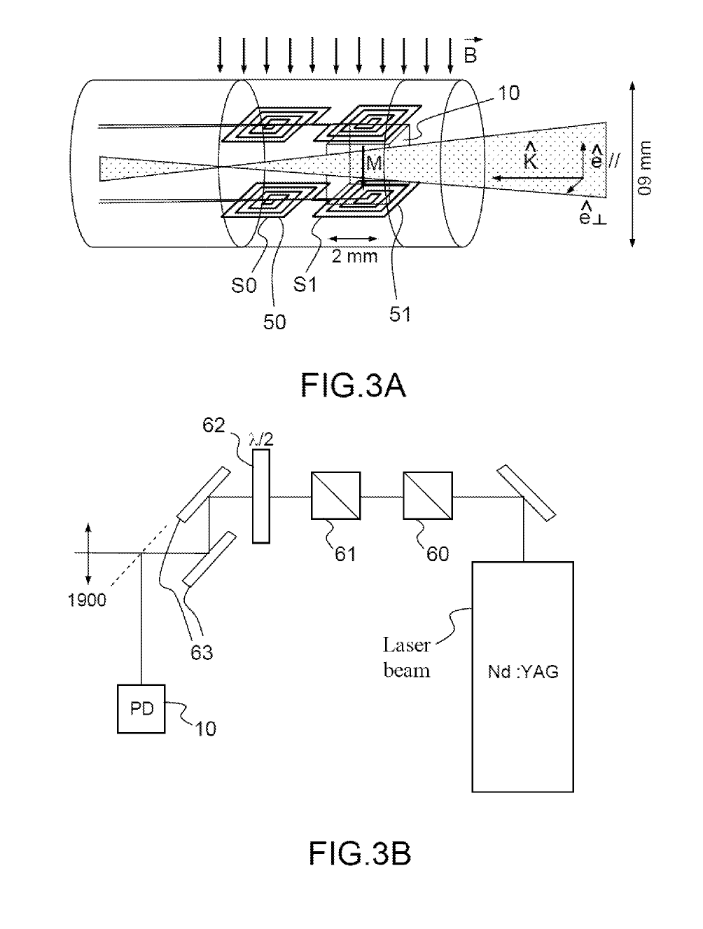

FIGS. 3A and 3B, a variant embodiment of the device of FIG. 2A, and

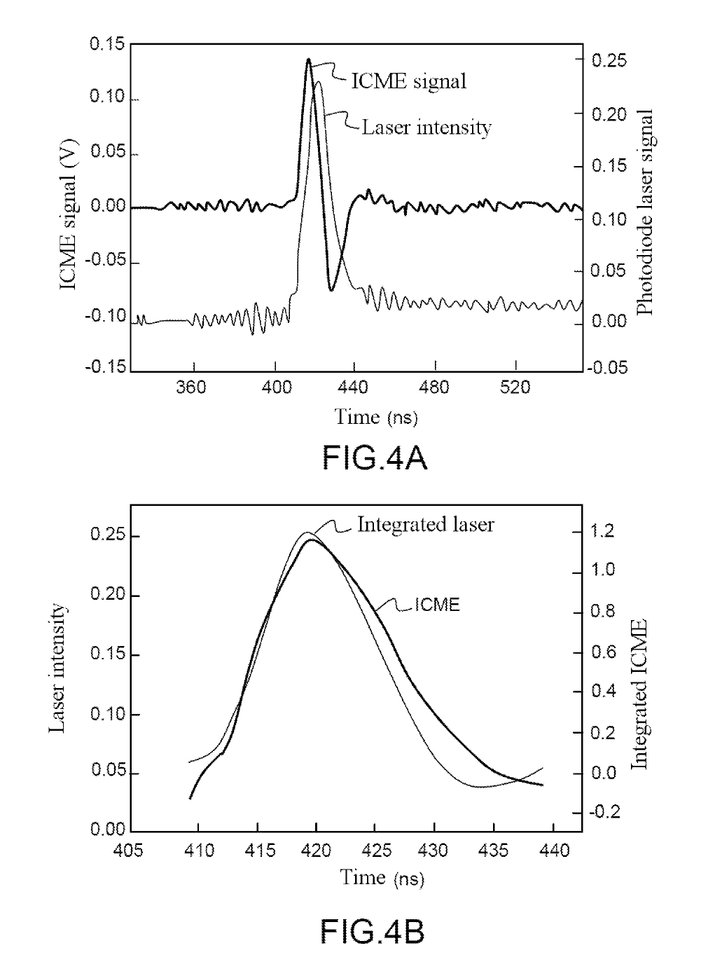

FIGS. 4A, 4B the results obtained by using a terbium gallium garnet crystal.

In a general manner, the device according to the invention makes it possible to measure a magnetization generated within an active medium when the active medium exhibits an Inverse Cotton-Mouton effect. The examples illustrated in the figures relate to an application to the characterization of a pulsed or continuous laser beam, but can without departing from the scope of the invention apply in the case of a linearly polarized electromagnetic wave.

FIG. 2A shows diagrammatically an exemplary device given so as to illustrate the elements of the device 1 according to the invention in the case of an application to the characterization of a pulsed laser beam.

In this FIG. 2A an active medium 10, is disposed between two permanent magnets 11, 12 which provide a transverse static magnetic field Bₜ oriented perpendicularly to the direction of propagation Dₗ of the laser beam 13 to be characterized, under the effect of an exterior magnetic field. Two pickup coils 14, 15, for example, detect the magnetization signal due to the propagation of the laser beam in the active medium and to the presence of the magnetic field Bₜ. This magnetization signal is variable as a function of the time. The pickup coils 14, 15 are, for example, placed on either side of the active medium 10. The normal to their surface A₁₄, A₁₅, is oriented parallel to the magnetic field Bₜ. The electrical signals S₁₄, S₁₅ generated at the level of each of the coils are transmitted to an electronic measurement circuit, an exemplary embodiment of which is given in FIG. 2B.

In the case of an active medium of ferromagnetic type, it is not necessary to use an exterior magnetic field Bₑₓₜ to obtain the inverse Cotton-Mouton effect, the magnetic field Bₜ is intrinsic to the material.

The device can also be used to characterize a continuous laser beam. In this case, the transverse magnetic field intrinsic to the material Bₜ, or the magnetic field Bₑₓₜ used, is a time-variable magnetic field, whose law of temporal variation is known. In this case, it is possible to measure the value of a constant or substantially constant power of the continuous laser beam.

In the case of an electromagnetic wave, passing through an active medium, the same device applies. The measurement device makes it possible to characterize the electromagnetic wave by at least one of the following parameters: the instantaneous power of the electromagnetic wave, the integral power or else the polarization of the wave.

The shape and the number of turns of the coils are chosen as a function for example of the magnetic flux variation. It is possible to use pickup coils of planar type. It would also be conceivable to use coils having a curved surface which best follows the field lines of the exterior magnetic field.

The example given refers to two coils, but without departing from the scope of the invention, it would be possible to perform the characterization of the laser beam or of an electromagnetic wave by using a single pickup coil or a number of coils greater than 2, depending on the application. Likewise, as will be presented in FIG. 3A, the pickup coils can be connected to compensation coils making it possible to limit, or indeed cancel out, spurious effects.

The active medium 10 is a medium which exhibits an inverse Cotton-Mouton effect when it is subjected to an exterior magnetic field Bₑₓₜ or else to the intrinsic magnetic field Bₜ in the case of a ferromagnetic medium or of other media which do not need any exterior enticement. It is thus possible to use crystal or glass. Liquid or gaseous active media can also be envisaged. The dimensions and the nature of the active medium will be chosen as a function of the desired application. For example, for a use within the framework of very intense lasers, it is possible to choose an active medium coupled to an optical adaptation system of dimensions such that the energy density of the beam remains below the damage threshold of the active medium. It will also be possible for the nature of the active medium to be chosen as a function of the wavelength of the laser.

FIG. 2A shows an optical adaptation system 20, represented by an input lens 201 and an output lens 202. This system makes it possible advantageously to adapt the size of the pulsed or continuous laser beam to be characterized to the dimensions of the apparatus. When the characterization device according to the invention is positioned in an existing system, this adaptation system makes it possible notably to adapt the size of the laser beam to be characterized to the existing optical systems in the system.

The assembly comprising the active medium 10, the magnets 11, 12 and the coils 14, 15 can be positioned inside a rotating mount 30 which makes it possible to rotate with respect to an axis A_{R} parallel to the direction of propagation of the laser beam so as to adjust the angle δ between the direction of the transverse magnetic field Bₜ and the polarization of the laser on which the value of the inverse Cotton-Mouton effect depends. By measuring the ICME signal as a function of the angle δ, it is possible to determine the laser polarization state, and in particular its ellipticity.

FIG. 2B represents an exemplary electronic circuit 2 associated with the device for characterizing the pulsed laser beam.

In this example, the two pickup coils 14, 15 of FIG. 2A are connected to a summator and low-noise amplifier 40 whose function is to eliminate the spurious noise not corresponding to the signal associated with the inverse Cotton-Mouton effect. The summed and amplified signal Sₜ is transmitted to a high-pass filter 41, and then to an integrator 42 before being transmitted to a display device 43 and/or to a storage memory 44.

This electronic circuit can without departing from the scope of the invention be implemented for application to a measurement of magnetization generated within an active medium or else in order to characterize a continuous laser beam.

The operating principle of the device according to the invention is, for example, as follows: the device for characterizing a laser beam or an electromagnetic wave according to the invention is positioned in the optical path of the laser beam or of the electromagnetic wave to be characterized (measurement of the instantaneous power, of the total power and/or of the polarization). The optical adaptation system when it is present is optimized in such a way that the laser beam or the wave to be characterized preserves the characteristics at its desired prime use after passage through the device, in the active medium. In the case of the measurement of a magnetization (electromagnetic wave), the optical adaptation system will be defined by taking account of the characteristics of this electromagnetic wave.

A way of proceeding when it is desired to ascertain the direction of the polarization of a linearly polarized pulsed or continuous laser beam is to use the rotating mount and to maximize the value displayed on the device. In this case, the mount is rotated until a maximum signal is read off at the level of the display device. The mount being graduated, its position gives the direction of the polarization of the beam. It is also possible to use this scheme to ascertain the polarization of a linearly polarized electromagnetic wave.

The example which follows was obtained in the case of a pulsed laser, by using a TGG or terbium gallium garnet crystal as active medium. The laser source used is a Nd:YAG laser (lambda=1064 nm) generating light pulses of a duration of 10 ns and an energy of about 0.5 J/pulse. The example is illustrated in FIGS. 3A and 3B.

Changes in the magnetization of the crystal were measured using a device comprising a dual-pickup coil such as that described in FIG. 2A, but this time consisting of a compensation coil 50 and of a measurement coil 51. FIG. 3A represents a part of the measurement device constituting the measurement zone. The signal coil 51 is placed in contact with the crystal 10 to be characterized, while the compensation coil 50 is disposed a certain distance away. The characteristics and the shape of this dual coil (signal and compensation) are chosen in such a way that any signal which does not result from the crystal is canceled out. The distance between the centers of each of the coils is, for example, 5 mm. Each pickup coil is calibrated by measuring the signal obtained in a known modulated magnetic field. The output signal of the coils is amplified by a low-noise fast amplifier and filtered through a high-pass filter. Two identical setups are used, on either side of the crystal.

In FIG. 3B, the laser beam passes through 2 polarizers 60, 61. The second polarizer 61 fixes the polarization of the beam while the first polarizer 60 is used to change the laser power delivered to the TGG crystal by rotating its axis of rotation with respect to the direction of polarization given by the first polarizer. A half-wave plate 62 is placed after the polarizers so as to rotate the laser polarization if necessary. Follower mirrors 63 and a lens make it possible to deliver and to focus the laser beam a few centimeters behind the TGG crystal. The size of the crystal is 2*2*2 mm. In this example, the shape of the crystal is a cube immersed in a magnetic field parallel to the [0, 0, 1] direction. The value of the field lay in the interval[0-2.5 T]. The vector k of the light in this application is parallel to the [0, 0, 1] direction and perpendicular to the external magnetic field, that is to say parallel to the [0, 1, 0] direction. Hereinafter the sign ∥ indicates a quantity measured for a polarization of the light parallel to the magnetic field and a sign ⊥ a quantity measured with a polarization of light perpendicular to the external field.

In FIG. 4A are represented a typical laser pulse with the corresponding signal detected by one of the two coil signals. The two signals are recorded on an oscilloscope with 1 GS/s.

The pulsed laser beam is controlled by extracting a small part of the beam injected into the crystal with a beam splitter. A fast diode is used to control the laser pulse. The photodiode was calibrated with respect to a device measuring the pulsed energy reaching the crystal.

The ICME magnetization in a TGG crystal can be defined as follows:

M=C_{ICM}P_{d}Bₑₓₜ( 1)

where C_{ICM} designates the constant of the Inverse Cotton-Mouton effect specific to the active medium, P_{d} the power density of the light beam and Bₑₓₜ the external magnetic field. The relation remains valid for a magnetic field intrinsic to the material.

This magnetization can be measured with the aid of a pickup coil if it varies over time. Indeed, the variation of the magnetization M(t) induces a potential difference V(t) across the terminals of the measurement coil in accordance with the relation

$$V ( t ) = - g {A}_{e} \frac{d {B}_{p} ( t )}{d t} \qquad ( 2 )$$

where g is the gain of the amplifier of the measurement coil. Aₑ=10 mm² is the effectively calibrated zone of the signal coil and Bₚ is the density of the magnetic flux through the surface of the measurement coil produced by the magnetization M of the crystal.

It is then noted that the temporal variation of Bₚ(t) can be achieved in two ways (see relation (1)):

a) by varying the power density P_{d} of the beam (pulsed or modulated laser),

b) by varying the external magnetic field.

In case a), the variation of Bₚ(t) may be written:

$$d {B}_{p} ( t ) / d t = bBext \frac{d {P}_{d} ( t )}{d t} \qquad ( 3 )$$

and the ICME signal V(t) may then be written:

$$V ( t ) = - g {A}_{e} b Bext \frac{d {P}_{d} ( t )}{d t} \qquad ( 4 )$$

where P_{d} is the density of the laser beam, Bₑₓₜ is the transverse static magnetic field and b is a proportionality factor characterizing the ICME value. This factor depends on the properties of the medium which is illuminated by the laser beam and thus magnetized.

Thus, the ICME signal is proportional to the time derivative of the intensity of the pulsed laser as is represented in FIG. 4A showing in a chart with time axis the value of the ICME signal and the value of the laser intensity.

FIG. 4B represents the magnetic flux density for a magnetic field value of 2.5 T modifying the value of the pulse energy from 0 to 0.250 J. The data were obtained in two configurations of the laser polarization: one parallel to the magnetic field corresponding to the measured magnetic flux density Bp∥, the other perpendicular to the magnetic field corresponding to Bp⊥. The diameter of the laser spot in the crystal was 1.2 mm, corresponding to a laser energy density Pd lying in the range 0-2.2×10¹³ W/m². FIG. 4B shows that the magnetic flux density depends linearly on the laser power density.

For a magnetization M of 1 A/m, a magnetic field density of about 4×10⁻⁸ T was found. By using a conversion factor f to convert between the value of the density of the flux Bp and the magnetization M of the crystal of about 2.5×10⁷ (A/m) T⁻¹.

In case b), by varying the external magnetic field the variation of Bₚ(t) may be written:

$$d {B}_{p} ( t ) / d t = b \times {P}_{d} \times \frac{d {B}_{ext}}{d t}$$

The ICME signal V(t) may then be written:

$$V ( t ) = - g \times {A}_{e} \times b \times {P}_{d} \times \frac{d {B}_{ext}}{d t}$$

This time the beam is continuous and it is the magnetic field which is pulsed.

The invention offers notably the following advantages:
measure at one and the same time the instantaneous power of a pulsed laser beam of high power with a temporal response of less than a nanosecond, the total energy of the laser pulse and the polarization of the beam;
measure the power of a continuous laser if a variable magnetic field is applied;
carry out a measurement of magnetization within a material which exhibits an Inverse Cotton-Mouton effect.

The device according to the invention can combine three functionalities which, in the prior art apparatuses known to the Applicant are in general separate.

Another advantage afforded by the device and the method according to the invention is the ability to perform the measurements described previously, without needing to extract or to attenuate a part of the beam. The device presented can be inserted into an existing optical circuit without modifying it. It therefore makes it possible to view the laser pulse and to measure its characteristics during the actual use of the beam.

According to an exemplary use, the magnetic field/pickup coil assembly can be disposed around a laser crystal, in order to measure the temporal evolution of the power in the crystal. Another possibility is to integrate the system into a Faraday isolator becoming at one and the same time a standard isolator and a power measurement apparatus.

1. A device making it possible to measure a magnetization generated within an active medium or to characterize a linearly polarized electromagnetic wave when said active medium exhibits an Inverse Cotton-Mouton effect, comprising:
an active medium in which a linearly polarized electromagnetic wave propagates,
a means for producing a transverse magnetic field Bₜ with respect to the direction of propagation Dₗ of said electromagnetic wave,
a device for measuring the electrical signal suitable for manifesting the magnetization generated within said active medium by said electromagnetic wave.

2. The device as claimed in claim 1, wherein the electromagnetic wave is a pulsed laser beam, said measurement device being suitable for characterizing said pulsed laser beam by at least one of the following parameters: the instantaneous power of a pulse of said laser beam, the integral power of a pulse of said laser beam, or the polarization of said laser beam.

3. The device as claimed in claim 1, wherein the electromagnetic wave is a continuous laser beam, the transverse magnetic field being variable over time and in that said measurement device being suitable for characterizing said continuous laser beam by at least one of the following parameters: the instantaneous power of said laser beam, the integral power, or the polarization of said laser beam.

4. The device as claimed in claim 1, wherein said active medium is subjected to a static exterior magnetic field Bₑₓₜ having a constant or variable value over time.

5. The device as claimed in claim 1, wherein the device for measuring the signal comprises at least one coil of pickup type.

6. The device as claimed in claim 5, wherein the device for measuring the signal comprises at least two coils of pickup type placed on either side of the active medium, the normal to their surface (A₁₄, A₁₅), being oriented substantially parallel to the magnetic field Bₑₓₜ.

7. The device as claimed in claim 1, wherein said electronic device for measuring the signal suitable for manifesting the instantaneous energy value of the electromagnetic wave, or the value of the power of the electromagnetic wave comprises the following elements:
a summator and low-noise amplifier whose function is to eliminate the spurious noise not corresponding to the signal associated with the inverse Cotton-Mouton effect, the summed and amplified signal being transmitted to,
a high-pass filter, and then to an integrator before being transmitted to a display device and/or to a storage memory.

8. The device as claimed in claim 1, further comprising a rotating mount in which are disposed the active medium, the means for producing the magnetic field.

9. The device as claimed in claim 2, further comprising an optical adaptation system.

10. The device as claimed in claim 1, wherein said active medium is a crystal of TGG or Terbium Gallium Garnet.

11. A method for measuring a magnetization generated within an active medium when said active medium exhibits an Inverse Cotton-Mouton effect, by using the device as claimed in claim 1, comprising:
transmitting in an active medium a linearly polarized electromagnetic wave,
generating a transverse magnetic field Bₜ with respect to the direction of propagation Dₗ of said electromagnetic wave,
measuring the electrical signal manifesting the magnetization generated within said active medium by said electromagnetic wave.

12. The device as claimed in claim 3, comprising an optical adaptation system.
